(19) United States
(12) Patent Application Publication
(10) Pub. No.: US 2024/0096967 A1
(43) Pub. Date: Mar. 21, 2024

(54) SEMICONDUCTOR DEVICE AND METHOD FOR MANUFACTURING SEMICONDUCTOR DEVICE

(71) Applicant: KABUSHIKI KAISHA TOSHIBA, Tokyo (JP)

(72) Inventor: Tatsuo SHIMIZU, Shinagawa Tokyo (JP)

(73) Assignee: KABUSHIKI KAISHA TOSHIBA, Tokyo (JP)

(21) Appl. No.: 18/177,318

(22) Filed: Mar. 2, 2023

(30) Foreign Application Priority Data
Sep. 15, 2022 (JP) 2022-147348

(51) Int. Cl. H01L 29/20; H01L 29/66; H01L 29/778

(52) U.S. Cl. CPC H01L 29/2003; H01L 29/66462; H01L 29/7786

(57) ABSTRACT

A semiconductor device of an embodiment includes a first gallium nitride region being an n-type semiconductor, and a second gallium nitride region in contact with the first gallium nitride region, the second gallium nitride region being metal, the second gallium nitride region containing a first element being at least one element selected from a group consisting of Be, Mg, Ca, Sr, Ba, Sc, Y, La, Ce, Pr, Nd, Pm, Sm, Eu, Gd, Tb, Dy, Ho, Er, Tm, Yb, Lu, V, Nb, Ta, Li, Na, K, Rb, Ce, and Zn.

### CROSS-REFERENCE TO RELATED APPLICATION

This application is based upon and claims the benefit of priority from Japanese Patent Application No. 2022-147348, filed on Sep. 15, 2022, the entire contents of which are incorporated herein by reference.

### FIELD

Embodiments described herein relate generally to a semiconductor device and a method for manufacturing a semiconductor device.

### BACKGROUND

Semiconductor elements, such as transistors and diodes, are used in circuits, such as switching power supply circuits and inverter circuits. These semiconductor elements are required to have high breakdown voltage and low on-resistance. The relation between breakdown voltage and on-resistance has a trade-off relation determined by the element material.

Advances in technological development have enabled semiconductor elements to achieve low on-resistance close to the limits of silicon, which is the major element material used for semiconductor elements. In order to further improve breakdown voltage or further reduce on-resistance, it is necessary to change the element material. By using a nitride semiconductor, such as gallium nitride or aluminum gallium nitride, as an element material for semiconductor elements, the trade-off relation determined by the element material can be improved. This enables dramatically higher breakdown voltages and lower on-resistance of semiconductor elements.

When nitride semiconductors are used to form semiconductor elements, it is desirable to achieve metal electrodes with low connection resistance to nitride semiconductors. Forming metal electrodes with low connection resistance to nitride semiconductors can achieve higher performance of semiconductor elements. The connection resistance may be called contact resistance.

### BRIEF DESCRIPTION OF THE DRAWINGS

FIG. 1 is a schematic sectional view illustrating a semiconductor device of a first embodiment;

FIG. 2 is a diagram illustrating a manufacturing procedure of a method for manufacturing the semiconductor device of the first embodiment;

FIGS. 3A and 3B are diagrams for explaining functions and effects of the semiconductor device of the first embodiment; and

FIG. 4 is a schematic sectional view illustrating a semiconductor device of a second embodiment.

### DETAILED DESCRIPTION

A semiconductor device of an embodiment includes a first gallium nitride region being an n-type semiconductor, and a second gallium nitride region in contact with the first gallium nitride region, the second gallium nitride region being metal, and the second gallium nitride region containing a first element being at least one element selected from a group consisting of beryllium (Be), magnesium (Mg), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn).

Hereinafter, embodiments of the present disclosure will be described with reference to the drawings. Note that, in the following description, the same reference signs are assigned to the same or similar members, and the description of the member that has been described will be omitted.

In this specification, the upper part of the drawing is described as “upper” and the lower part of the drawing as “lower” to indicate the positional relation of parts or the like. In the present specification, the terms “upper” and “lower” do not necessarily indicate the relation with the gravity direction.

In the following description, n⁺, n, and n⁻, or p⁺, p, and p⁻ represent relative levels of impurity concentration in each conductive type. That is, n⁺ has a relatively higher n-type impurity concentration than n, and n⁻ has a relatively lower n-type impurity concentration than n. Furthermore, p⁺ has a relatively higher p-type impurity concentration than p, and p⁻ has a relatively lower p-type impurity concentration than p. Note that, an n⁺-type and an n⁻-type will be also simply referred to as an n-type, and a p⁺-type and a p⁻-type will be also simply referred to as a p-type.

### First Embodiment

A semiconductor device of a first embodiment includes a first gallium nitride region being an n-type semiconductor, and a second gallium nitride region in contact with the first gallium nitride region. The second gallium nitride region is metal and the second gallium nitride region contains a first element being at least one element selected from a group consisting of beryllium (Be), magnesium (Mg), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn).

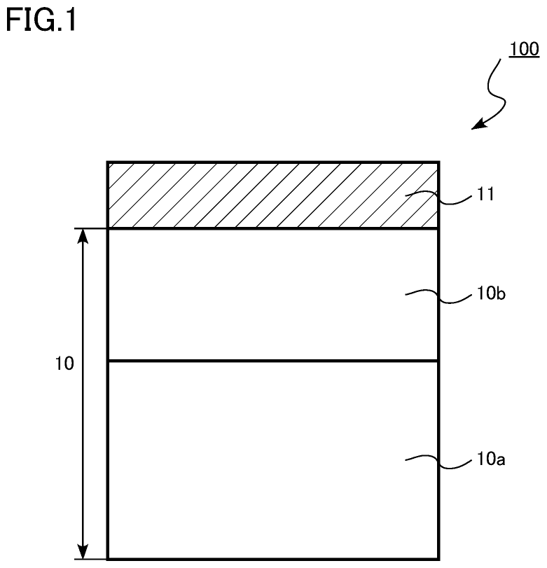

FIG. 1 is a schematic sectional view illustrating the semiconductor device of the first embodiment. The semiconductor device of the first embodiment has a contact structure 100 that electrically connects a gallium nitride layer and a metal electrode.

The contact structure 100 of the first embodiment includes a gallium nitride layer 10 and a metal electrode 11. The gallium nitride layer 10 includes a first gallium nitride region 10a and a second gallium nitride region 10b.

The gallium nitride layer 10 is, for example, single-crystal gallium nitride.

The first gallium nitride region 10a is an n-type semiconductor. The first gallium nitride region 10a is gallium nitride of the n-type semiconductor. The first gallium nitride region 10a contains, for example, silicon (Si) as an n-type impurity. The n-type impurity concentration of the first gallium nitride region 10a is, for example, 1×10¹⁸ cm⁻³ or more and 1×10²¹ cm⁻³ or less.

The second gallium nitride region 10b is provided on the first gallium nitride region 10a. The second gallium nitride region 10b is in contact with the first gallium nitride region 10a. The second gallium nitride region 10b is provided between the first gallium nitride region 10a and the metal electrode 11.

The second gallium nitride region 10b is metal. The second gallium nitride region 10b is gallium nitride of the metal. The second gallium nitride region 10b is gallium nitride which is metallized gallium nitride of a semiconductor.

For example, since the second gallium nitride region 10b is metal, the electrical resistance of the second gallium nitride region 10b increases as the temperature rises.

The sheet resistance of the second gallium nitride region 10b is, for example, 0.1 Ω/sq or less.

The work function of the second gallium nitride region 10b is, for example, 3.7 eV or less. The work function of the second gallium nitride region 10b can be measured using, for example, ultraviolet photoelectron spectroscopy (UPS), X-ray photoelectron spectroscopy (XPS), or Auger electron spectroscopy (AES). In addition, a Kelvin probe can also be used to measure the work function difference between the metal of a sample and the metal of the probe.

The second gallium nitride region 10b contains a first element being at least one element selected from a group consisting of beryllium (Be), magnesium (Mg), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn).

The concentration of the first element contained in the second gallium nitride region 10b is, for example, 1×10¹⁹ cm⁻³ or more and 1×10²² cm⁻³ or less.

The thickness of the second gallium nitride region 10b is, for example, 0.1 μm or more and 1.0 μm or less.

Of the first element contained in the second gallium nitride region 10b, the amount of the first element bonded to gallium (Ga) is greater than, for example, the amount of the first element bonded to nitrogen (N). In other words, of the first element contained in the second gallium nitride region 10b, the amount of the first element disposed at the nitrogen site of the crystal structure of the gallium nitride is greater than the amount of the first element disposed at the gallium site of the crystal structure of the gallium nitride. In other words, the amount of the first element substituted for nitrogen atoms in the crystal structure of the gallium nitride is greater than the amount of the first element substituted for gallium atoms in the crystal structure of the gallium nitride.

Of the first element contained in the second gallium nitride region 10b, the amount of the first element bonded to gallium (Ga) is, for example, 10 times or more the amount of the first element bonded to nitrogen (N). In other words, of the first element contained in the second gallium nitride region 10b, the amount of the first element disposed at the nitrogen site of the crystal structure of the gallium nitride is, for example, 10 times or more the amount of the first element disposed at the gallium site of the crystal structure of the gallium nitride.

The relation between the amount of the first element bonded to gallium (Ga) and the amount of the first element bonded to nitrogen (N) can be measured using, for example, X-ray photoelectron spectroscopy (XPS).

The metal electrode 11 is provided on the second gallium nitride region 10b. The metal electrode 11 is in contact with the second gallium nitride region 10b.

The metal electrode 11 is metal or a metal compound. The chemical composition of the metal electrode 11 is different from the chemical composition of the second gallium nitride region 10b.

The metal electrode 11 contains, for example, titanium, titanium nitride, aluminum, or tungsten. The metal electrode 11 has, for example, a stacked structure of a titanium film and an aluminum film.

Next, an example of a method for manufacturing the semiconductor device of the first embodiment will be described.

A method for manufacturing the semiconductor device of the first embodiment includes performing a first ion implantation for implanting, into an n-type gallium nitride layer, a first element being at least one element selected from a group consisting of beryllium (Be), magnesium (Mg), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn), performing a second ion implantation for implanting gallium (Ga) into the gallium nitride layer, performing a third ion implantation for implanting hydrogen (H) into the gallium nitride layer, forming a covering layer on the surface of the gallium nitride layer after the first ion implantation, the second ion implantation, and the third ion implantation, performing a first heat treatment after the forming the covering layer, removing the covering layer after the first heat treatment, and performing a second heat treatment after the removing the covering layer.

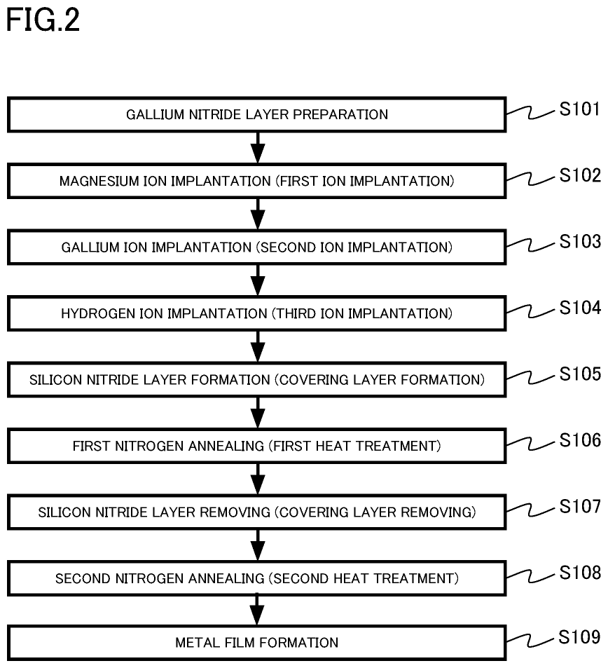

FIG. 2 is a diagram illustrating a manufacturing procedure of the method for manufacturing the semiconductor device of the first embodiment. The method for manufacturing the semiconductor device of the first embodiment includes a gallium nitride layer preparation step S101, a magnesium ion implantation step S102 (first ion implantation), a gallium ion implantation step S103 (second ion implantation), a hydrogen ion implantation step S104 (third ion implantation), a silicon nitride layer formation step S105 (covering layer formation), a first nitrogen annealing step S106 (first heat treatment), a silicon nitride layer removing step S107 (covering layer removing), a second nitrogen annealing step S108 (second heat treatment), and a metal film formation step S109.

Hereinafter, description will be given with reference to FIG. 1. In addition, a case where the first element is magnesium (Mg) will be described as an example.

First, a gallium nitride layer 10 is prepared (S101). The gallium nitride layer 10 is single-crystal gallium nitride (GaN). In the gallium nitride layer 10, a first gallium nitride region 10a of an n-type semiconductor is formed.

Next, magnesium (Mg) is ion-implanted into the surface of the gallium nitride layer 10 using a known ion implantation method (S102). The ion implantation of magnesium corresponds to the first ion implantation.

The region into which magnesium is ion-implanted eventually becomes a second gallium nitride region 10b having the contact structure 100. For example, magnesium may be ion-implanted a plurality of times with different ion implantation energies.

The dose of magnesium is, for example, 1×10¹⁴ cm⁻² or more and 5×10¹⁵ cm⁻² or less.

Next, gallium (Ga) is ion-implanted into the surface of the gallium nitride layer 10 using a known ion implantation method (S103). The ion implantation of gallium corresponds to the second ion implantation.

Gallium is introduced into the region into which magnesium has been ion-implanted. For example, gallium may be ion-implanted a plurality of times with different ion implantation energies.

The dose of gallium is greater than the dose of magnesium, for example. The dose of gallium is, for example, 5×10¹⁴ cm⁻² or more and 1×10¹⁶ cm⁻² or less.

The second ion implantation forms a large amount of nitrogen vacancies in the gallium nitride layer 10, for example.

Next, hydrogen (H) is ion-implanted into the surface of the gallium nitride layer 10 using a known ion implantation method (S104). The ion implantation of hydrogen corresponds to the third ion implantation.

Hydrogen is introduced into the region into which magnesium and gallium have been ion-implanted. For example, hydrogen may be ion-implanted a plurality of times with different ion implantation energies.

The dose of hydrogen in the third ion implantation is greater than the dose of magnesium in the first ion implantation, for example. The dose of hydrogen in the third ion implantation is greater than the dose of gallium in the second ion implantation, for example. The dose of hydrogen is, for example, 1×10¹⁵ cm⁻² or more and 5×10¹⁶ cm⁻² or less.

Next, a silicon nitride layer is formed on the surface of the gallium nitride layer 10 using a known film growth method (S105). The silicon nitride layer is an example of the covering layer. The covering layer is not limited to silicon nitride.

The covering layer is, for example, an insulator. The covering layer is, for example, silicon nitride, silicon oxide, silicon oxynitride, or aluminum nitride.

The covering layer is, for example, a conductor or a semiconductor. The covering layer is, for example, polycrystalline silicon.

Next, the first nitrogen annealing is performed (S106). The first nitrogen annealing is performed, for example, in a nitrogen gas atmosphere under a temperature condition of 950° C. or higher and 1250° C. or lower. The first nitrogen annealing is an example of the first heat treatment.

The first heat treatment is performed, for example, in a non-oxidizing atmosphere containing argon, nitrogen, hydrogen, or helium.

The first heat treatment allows magnesium to enter the nitrogen site of the gallium nitride, for example. The first heat treatment allows magnesium to enter the nitrogen vacancies, for example. Magnesium having entered the nitrogen site of the gallium nitride is bonded to hydrogen, for example.

Next, the silicon nitride layer on the surface of the gallium nitride layer 10 is removed using a known wet etching method (S107). The surface of the gallium nitride layer 10 is exposed.

Next, the second nitrogen annealing is performed (S108). The second nitrogen annealing is performed, for example, in a nitrogen gas atmosphere under a temperature condition of 950° C. or higher and 1250° C. or lower. The second nitrogen annealing is an example of the second heat treatment.

The second heat treatment is performed, for example, in a non-oxidizing atmosphere containing argon, nitrogen, or helium. The second heat treatment is performed, for example, in an atmosphere containing no hydrogen.

The second heat treatment removes hydrogen bonded to magnesium from the magnesium, for example.

Next, a stacked film of a titanium film and an aluminum film is formed on the gallium nitride layer 10 (S109). The stacked film of the titanium film and the aluminum film is an example of a metal film. The stacked film of the titanium film and the aluminum film eventually becomes a metal electrode 11 of the contact structure 100.

The contact structure 100 of the first embodiment illustrated in FIG. 1 is formed by the above manufacturing method.

Next, functions and effects of the semiconductor device and the method for manufacturing the semiconductor of the first embodiment will be described.

When nitride semiconductors are used to form semiconductor elements, it is desirable to achieve metal electrodes with low connection resistance to nitride semiconductors. Forming metal electrodes with low connection resistance to nitride semiconductors can achieve higher performance of semiconductor elements.

Since the contact structure 100 of the first embodiment includes the second gallium nitride region 10b of metal, it is possible to achieve a highly reliable metal electrode with low connection resistance to an n-type gallium nitride region. Details will be described below.

The junction between a gallium nitride region of an n-type semiconductor and a metal electrode is a junction between a semiconductor and metal. From the viewpoint of work function, there are very limited metal materials that can be used for an ohmic junction with n-type gallium nitride. Considering the affinity of metal materials for semiconductor processes, it is difficult for the junction between a gallium nitride region of an n-type semiconductor and a metal electrode to be an ohmic junction. Therefore, there is a high possibility that the junction between a gallium nitride region of an n-type semiconductor and a metal electrode is to be a Schottky junction. Consequently, it is difficult to lower the connection resistance between a gallium nitride region of an n-type semiconductor and a metal electrode.

In addition, the interface between a gallium nitride region of an n-type semiconductor and a metal electrode is an interface between a semiconductor and metal. For this reason, the strength of the interface can decrease due to the application of temperature or stress. Therefore, peel-off of the metal electrode may occur at the interface, which lower the reliability of the metal electrode, for example.

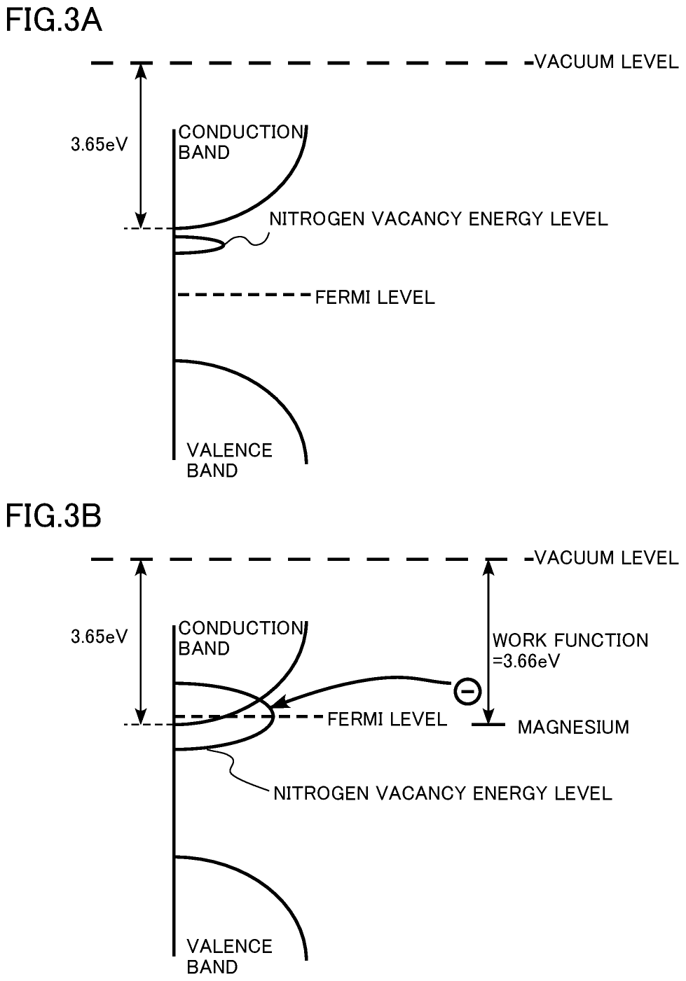

FIGS. 3A and 3B are diagrams for explaining functions and effects of the semiconductor device of the first embodiment. FIG. 3A is an energy band diagram of undoped gallium nitride in which conductive impurities are not actively introduced. FIG. 3B is an energy band diagram of gallium nitride of metal corresponding to the second gallium nitride region 10b of the first embodiment.

A certain amount of nitrogen vacancies is present in the undoped gallium nitride. As illustrated in FIG. 3A, the undoped semiconductor gallium nitride has a nitrogen vacancy energy level below the lower end of the conduction band. The nitrogen vacancy energy level is present in the vicinity of the lower end of the conduction band. The energy at the lower end of the conduction band of the gallium nitride is 3.65 eV.

In the gallium nitride of the metal, magnesium (Mg) is present at the nitrogen site of the gallium nitride. As illustrated in FIG. 3B, the work function of the magnesium has energy in the vicinity of the lower end of the conduction band. In other words, the work function of the magnesium has energy in the vicinity of the nitrogen vacancy energy level.

According to the first principle calculation by the inventor, it has been found that when a large amount of nitrogen vacancies and magnesium present at the nitrogen site coexist in gallium nitride, electrons are supplied from magnesium to the nitrogen vacancies. Then, it has been found that when electrons are supplied from magnesium to the nitrogen vacancies, the nitrogen vacancy energy band expands. Furthermore, it has been found that the Fermi level of gallium nitride is disposed in the conduction band.

In gallium nitride of metal, the interaction of a large amount of nitrogen vacancies with magnesium at the nitrogen site brings the Fermi level into the conduction band, and the gallium nitride, which is originally a semiconductor, is metallized.

The contact structure 100 of the first embodiment includes the second gallium nitride region 10b of metal between the first gallium nitride region 10a of the n-type semiconductor and the metal electrode 11. The junction between the second gallium nitride region 10b of the metal and the metal electrode 11 is an intermetallic junction. Therefore, the junction between the second gallium nitride region 10b of the metal and the metal electrode 11 is an ohmic junction, which can lower the connection resistance.

In addition, since the interface between the second gallium nitride region 10b of the metal and the metal electrode 11 is an interface between metal and metal, the decrease in strength due to the application of temperature or stress can be suppressed. Therefore, peel-off of the metal electrode 11 at the interface is suppressed, and the reliability of the metal electrode 11 is improved, for example.

The junction between the first gallium nitride region 10a of the n-type semiconductor and the second gallium nitride region 10b of the metal is a junction between a semiconductor and metal. As described above, the Fermi level of the second gallium nitride region 10b is within the conduction band of the gallium nitride. In other words, the work function of the second gallium nitride region 10b is smaller than the energy at the lower end of the conduction band of the first gallium nitride region 10a. Therefore, the junction between the first gallium nitride region 10a of the n-type semiconductor and the second gallium nitride region 10b of the metal is an ohmic junction. Consequently, the connection resistance between the first gallium nitride region 10a of the n-type semiconductor and the second gallium nitride region 10b of the metal can be lowered.

The interface between the first gallium nitride region 10a of the n-type semiconductor and the second gallium nitride region 10b of the metal is an interface in which a crystal structure of the gallium nitride is continuous. Therefore, the strength of the interface is high. Accordingly, even when annealing or the like is performed in a subsequent process, residual oxygen or the like does not enter the continuous interface, and interface peel-off is difficult to occur.

As described above, since the contact structure 100 of the first embodiment includes the second gallium nitride region 10b of metal, the junction between the n-type first gallium nitride region 10a and the metal electrode 11 is an ohmic junction. Consequently, the highly reliable metal electrode 11 with low connection resistance to the n-type first gallium nitride region 10a can be achieved. As a secondary effect, the degree of freedom in selection of the metal electrode 11 is greatly improved. For example, a special stacked structure, such as a stacked structure of aluminum and titanium, is not required. For example, titanium nitride (TiN), tungsten (W), polysilicon doped with phosphorus or boron, or the like having excellent workability can be used.

From the viewpoint of reducing the connection resistance of the metal electrode 11, the work function of the second gallium nitride region 10b is preferably 3.7 eV or less.

From the viewpoint of reducing the connection resistance of the metal electrode 11, the sheet resistance of the second gallium nitride region 10b is preferably 0.1 Ω/sq or less.

From the viewpoint of reducing the connection resistance of the metal electrode 11, the magnesium concentration of the second gallium nitride region 10b is preferably 1×10¹⁹ cm⁻³ or more, more preferably 1×10²⁰ cm⁻³ or more, and still more preferably 1×10²¹ cm⁻³ or more.

From the viewpoint of reducing the connection resistance of the metal electrode 11, the amount of magnesium bonded to gallium of the magnesium contained in the second gallium nitride region 10b is preferably greater than the amount of magnesium bonded to nitrogen, and the amount of magnesium bonded to gallium of the magnesium contained in the second gallium nitride region 10b is more preferably 10 times or more the amount of magnesium bonded to nitrogen.

In other words, the amount of magnesium disposed at the nitrogen site of the magnesium contained in the second gallium nitride region 10b is preferably greater than the amount of magnesium disposed at the gallium site. In addition, the amount of magnesium disposed at the nitrogen site of the magnesium contained in the second gallium nitride region 10b is preferably 10 times or more the amount of magnesium disposed at the gallium site.

Magnesium disposed at the gallium site functions as a p-type impurity. Therefore, the presence of magnesium disposed at the gallium site is undesirable because it interferes with the metallic properties of the second gallium nitride region 10b.

In the manufacturing method of the first embodiment, the second gallium nitride region 10b is formed by ion-implanting magnesium, gallium, and hydrogen into the same region of the gallium nitride layer 10. By ion-implanting gallium having a relatively large ionic radius, a large amount of nitrogen vacancies is formed in the gallium nitride layer 10. Therefore, a large amount of nitrogen vacancies is present in the second gallium nitride region 10b.

Then, magnesium enters the nitrogen vacancies formed in a large amount. In other words, magnesium enters the nitrogen site. As described above, when magnesium enters the gallium site, magnesium functions as a p-type impurity, which is undesirable.

In the manufacturing method of the first embodiment, by ion implanting gallium, gallium preferentially enters the formed gallium vacancies over magnesium. Therefore, magnesium is inhibited from entering the gallium site.

Furthermore, by ion-implanting hydrogen, magnesium is promoted to enter the nitrogen vacancies. Magnesium bonded to hydrogen can exist more stably in nitrogen vacancies than magnesium alone.

On the other hand, magnesium bonded to hydrogen does not serve as an electron supply source to the nitrogen vacancy energy band. Therefore, hydrogen is desorbed from magnesium by the second heat treatment after the covering layer is removed in order for magnesium to function as an electron supply source.

As the first element, an element other than magnesium, that is, at least one element selected from a group consisting of beryllium (Be), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn) can be used to obtain functions and effects similar to those when magnesium is used.

In particular, among the above elements, an element whose work function is at energy in the vicinity of the lower end of the conduction band of gallium nitride or an element whose work function is smaller than the lower end of the conduction band of gallium nitride effectively functions as an electron supply source to the nitrogen vacancy energy band, and thus is preferable as the first element.

For example, cesium (Cs) having a work function of 1.9 eV, potassium (K) having a work function of 2.3 eV, niobium (Nb) having a work function of 2.3 eV, sodium (Na) having a work function of 2.4 eV, strontium (Sr) and barium (Ba) having a work function of 2.5 eV, calcium (Ca) having a work function of 2.8 eV, lithium (Li) having a work function of 2.9 eV, yttrium (Y) having a work function of 3.1 eV, scandium (Sc) having a work function of 3.5 eV, or zinc (Zn) having a work function of 3.6 eV is preferably used as the first element.

As described above, according to the semiconductor device and the method for manufacturing the semiconductor device of the first embodiment, it is possible to provide a semiconductor device capable of achieving a metal electrode with low connection resistance to a nitride semiconductor.

### Second Embodiment

A semiconductor device of a second embodiment is a vertical high electron mobility transistor (HEMT) including the contact structure of the first embodiment. Hereinafter, the description overlapping with the first embodiment will be partially omitted.

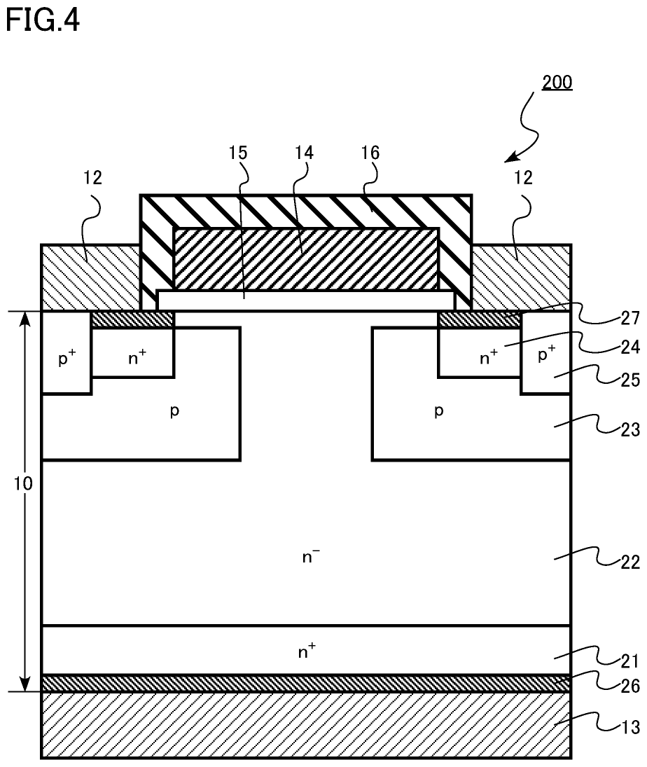

FIG. 4 is a schematic sectional view illustrating the semiconductor device of the second embodiment. The semiconductor device of the second embodiment is a vertical HEMT 200.

The vertical HEMT 200 of the second embodiment includes a gallium nitride layer 10, a source electrode 12 (metal electrode), a drain electrode 13 (metal electrode), a gate electrode 14, an aluminum nitride layer 15, and an interlayer insulating layer 16. The gallium nitride layer 10 includes an n⁺-type drain region 21 (first gallium nitride region), an n⁻-type drift region 22, a p-type body region 23, an n⁺-type source region 24 (first gallium nitride region), a p⁺-type contact region 25, a first metal region 26 (second gallium nitride region), and a second metal region 27 (second gallium nitride region).

The n⁺-type drain region 21 is an example of the first gallium nitride region. The n⁺-type drain region 21 is an n-type semiconductor. The drain region 21 is gallium nitride of the n-type semiconductor. The drain region 21 contains, for example, silicon (Si) as an n-type impurity. The n-type impurity concentration of the drain region 21 is, for example, 1×10¹⁸ cm⁻³ or more and 1×10²¹ cm⁻³ or less.

The first metal region 26 is an example of the second gallium nitride region.

The first metal region 26 is provided below the drain region 21. The first metal region 26 is in contact with the drain region 21. The first metal region 26 is provided between the drain region 21 and the drain electrode 13.

The first metal region 26 is metal. The first metal region 26 is gallium nitride of the metal. The first metal region 26 is gallium nitride which is metallized gallium nitride of a semiconductor.

The first metal region 26 contains a first element being at least one element selected from a group consisting of beryllium (Be), magnesium (Mg), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn).

Of the first element contained in the first metal region 26, the amount of the first element bonded to gallium (Ga) is greater than, for example, the amount of the first element bonded to nitrogen (N).

The drain electrode 13 is an example of the metal electrode. The drain electrode 13 is provided below the first metal region 26. The drain electrode 13 is in contact with the first metal region 26.

The drain electrode 13 is metal or a metal compound. The chemical composition of the drain electrode 13 is different from the chemical composition of the first metal region 26.

The n⁺-type source region 24 is an example of the first gallium nitride region. The source region 24 is an n-type semiconductor. The source region 24 is gallium nitride of the n-type semiconductor. The source region 24 contains, for example, silicon (Si) as an n-type impurity. The n-type impurity concentration of the source region 24 is, for example, 1×10¹⁸ cm⁻³ or more and 1×10²¹ cm⁻³ or less.

The second metal region 27 is an example of the second gallium nitride region.

The second metal region 27 is provided on the source region 24. The second metal region 27 is in contact with the source region 24. The second metal region 27 is provided between the source region 24 and the source electrode 12.

The second metal region 27 is metal. The second metal region 27 is gallium nitride of the metal. The second metal region 27 is gallium nitride which is metallized gallium nitride of a semiconductor.

The second metal region 27 contains a first element being at least one element selected from a group consisting of beryllium (Be), magnesium (Mg), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn).

Of the first element contained in the second metal region 27, the amount of the first element bonded to gallium (Ga) is greater than, for example, the amount of the first element bonded to nitrogen (N).

The source electrode 12 is an example of the metal electrode. The source electrode 12 is provided on the second metal region 27. The source electrode 12 is in contact with the second metal region 27.

The source electrode 12 is metal or a metal compound. The chemical composition of the source electrode 12 is different from the chemical composition of the second metal region 27.

The source region 24 contains, for example, silicon (Si) as an n-type impurity. For example, silicon, nitrogen, and hydrogen are simultaneously implanted. The p-type body region 23 and the p⁺-type contact region 25 contain, for example, magnesium (Mg) as a p-type impurity. Magnesium, nitrogen, and hydrogen are implanted simultaneously. Then, magnesium, gallium, and hydrogen are implanted to form the second metal region 27. Then, by proceeding with covering layer formation, a first heat treatment, covering layer removing, and second annealing, the source region 24, the p-type body region 23, the p⁺-type contact region 25, and the second metal region 27 are formed.

In the vertical HEMT 200 of the second embodiment, a contact structure similar to the contact structure 100 of the first embodiment is applied to the contact structure between the drain electrode 13 and the gallium nitride layer 10. Therefore, the connection resistance between the drain electrode 13 and the gallium nitride layer 10 is reduced. Furthermore, the reliability of the drain electrode 13 is improved.

In addition, in the vertical HEMT 200 of the second embodiment, a contact structure similar to the contact structure 100 of the first embodiment is applied to the contact structure between the source electrode 12 and the gallium nitride layer 10. Therefore, the connection resistance between the source electrode 12 and the gallium nitride layer 10 is reduced. Furthermore, the reliability of the source electrode 12 is improved.

Therefore, for example, the highly reliable vertical HEMT 200 with low on-resistance can be achieved.

Furthermore, in the vertical HEMT 200 of the second embodiment, any metal material capable of reducing the connection resistance with the p⁺-type contact region 25 can be selected as the electrode material for the source electrode 12.

As described above, according to the semiconductor device of the second embodiment, it is possible to provide a semiconductor device capable of achieving a metal electrode with low connection resistance to a nitride semiconductor.

In the second embodiment, the vertical HEMT has been described as an example of the semiconductor device, but the present disclosure can also be applied to other semiconductor devices. For example, the present disclosure can also be applied to an optical semiconductor device, such as a horizontal HEMT, a diode, or a light emitting diode (LED).

While certain embodiments have been described, these embodiments have been presented by way of example only, and are not intended to limit the scope of the inventions. Indeed, a semiconductor device and a method for manufacturing a semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a first gallium nitride region being an n-type semiconductor; and
a second gallium nitride region in contact with the first gallium nitride region, the second gallium nitride region being metal, the second gallium nitride region containing a first element being at least one element selected from a group consisting of beryllium (Be), magnesium (Mg), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn).

2. The semiconductor device according to claim 1, further comprising a metal electrode in contact with the second gallium nitride region.

3. The semiconductor device according to claim 1, wherein a work function of the second gallium nitride region is 3.7 eV or less.

4. The semiconductor device according to claim 1, wherein sheet resistance of the second gallium nitride region is 0.1 Ω/sq or less.

5. The semiconductor device according to claim 1, wherein a concentration of the first element in the second gallium nitride region is 1×10¹⁹ cm⁻³ or more.

6. The semiconductor device according to claim 1, wherein an amount of the first element bonded to gallium (Ga) is greater than an amount of the first element bonded to nitrogen (N).

7. A semiconductor device comprising:
a first gallium nitride region being an n-type semiconductor; and
a second gallium nitride region in contact with the first gallium nitride region, the second gallium nitride region containing a first element being at least one element selected from a group consisting of beryllium (Be), magnesium (Mg), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn), and the second gallium nitride region having an amount of the first element bonded to gallium (Ga) greater than an amount of the first element bonded to nitrogen (N).

8. The semiconductor device according to claim 7, further comprising a metal electrode in contact with the second gallium nitride region.

9. The semiconductor device according to claim 7, wherein a work function of the second gallium nitride region is 3.7 eV or less.

10. The semiconductor device according to claim 7, wherein sheet resistance of the second gallium nitride region is 0.1 Ω/sq or less.

11. The semiconductor device according to claim 7, wherein a concentration of the first element in the second gallium nitride region is 1×10¹⁹ cm⁻³ or more.

12. A method for manufacturing a semiconductor device comprising:
performing a first ion implantation for implanting first element into an n-type gallium nitride layer, the first element being at least one element selected from a group consisting of beryllium (Be), magnesium (Mg), calcium (Ca), strontium (Sr), barium (Ba), scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), vanadium (V), niobium (Nb), tantalum (Ta), lithium (Li), sodium (Na), potassium (K), rubidium (Rb), cesium (Cs), and zinc (Zn);
performing a second ion implantation for implanting gallium (Ga) into the gallium nitride layer;
performing a third ion implantation for implanting hydrogen (H) into the gallium nitride layer;
forming a covering layer on a surface of the gallium nitride layer after the performing the first ion implantation, the performing the second ion implantation, and the performing the third ion implantation;
performing a first heat treatment after the forming the covering layer;
removing the covering layer after the performing the first heat treatment; and
performing a second heat treatment after the removing the covering layer.

13. The method for manufacturing the semiconductor device according to claim 12, further comprising forming a metal film on the gallium nitride layer after the performing the second heat treatment.

14. The method for manufacturing the semiconductor device according to claim 12, wherein
a dose of hydrogen in the third ion implantation is greater than a dose of gallium (Ga) in the second ion implantation, and
the dose of gallium (Ga) in the second ion implantation is greater than a dose of the first element in the first ion implantation.
